(19) United States
(12) Patent Application Publication
(10) Pub. No.: US 2010/0151152 A1
(43) Pub. Date: Jun. 17, 2010

(54) Non-Stoichiometric SiOxNy Optical Filter Fabrication

(76) Inventors: Pooran Joshi, Vancouver, WA (US); Apostolos T. Voutsas, Portland, OR (US); John W. Hartzell, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(21) Appl. No.: 12/700,395

(22) Filed: Feb. 4, 2010

Related U.S. Application Data
(63) Continuation of application No. 11/789,947, filed on Apr. 26, 2007.

(51) Int. Cl. C23C 16/34; C23C 16/42; B05D 5/06

(52) U.S. Cl. 427/579

(57) ABSTRACT

A non-stoichiometric SiO_{X}N_{Y} thin-film optical filter is provided. The filter is formed from a substrate and a first non-stoichiometric SiO_{X1}N_{Y1} thin-film overlying the substrate, where (X1+Y1<2 and Y1>0). The first non-stoichiometric SiO_{X1}N_{Y1} thin-film has a refractive index (n1) in the range of about 1.46 to 3, and complex refractive index (N1=n1+ik1), where k1 is an extinction coefficient in a range of about 0 to 0.5. The first non-stoichiometric SiO_{X1}N_{Y1} thin-film may be either intrinsic or doped. In one aspect, the first non-stoichiometric SiO_{X1}N_{Y1} thin-film has nanoparticles with a size in the range of about 1 to 10 nm. A second non-stoichiometric SiO_{X2}N_{Y2} thin-film may overlie the first non-stoichiometric SiO_{X1}N_{Y1} thin-film, where Y1≠Y2. The second non-stoichiometric SiO_{X1}N_{Y1} thin-film may be intrinsic and doped. In another variation, a stoichiometric SiO_{X2}N_{Y2} thin-film, intrinsic or doped, overlies the first non-stoichiometric SiO_{X1}N_{Y1} thin-film.

### RELATED APPLICATIONS

This application is a continuation of a pending patent application entitled, NON-STOICHIOMETRIC SiOxNy OPTICAL FILTERS, invented by Pooran Joshi et al., Ser. No. 11/789,947, filed Apr. 26, 2007. This application is incorporated herein by reference.

### BACKGROUND OF THE INVENTION

1. Field of the Invention

This invention generally relates to the fabrication of optical filters, and more particularly, to a method for forming a non-stoichiometric silicon-oxide-nitride film optical filter, using a high-density plasma-enhanced chemical vapor deposition process.

2. Description of the Related Art

The fabrication of integrated optical devices involves the deposition of materials with the optical characteristics such as absorption, transmission, and spectral response. Thin-film fabrication techniques can produce diverse optical thin films, which are suitable for the production of large area devices at high throughput and yield. Some optical parameters of importance include refractive index and the optical band-gap, which dictate the transmission and reflection characteristics of the thin film.

Typically, bilayer or multilayer stack thin-films are required for the fabrication of optical devices with the desired optical effect. Various combinations of the metal, dielectric, and/or semiconductor layers are also used to form multilayer films with the desired optical characteristics. The selection of the material depends on the target reflection, transmission, and absorption characteristics. While a single layer device would obviously be more desirable, no single thin-film material has been able to provide the wide range of optical dispersion characteristics required to get the desired optical absorption, band-gap, refractive index, reflection, or transmission over a wide optical range extending from UV to far IR frequencies.

Silicon is the material of choice for the fabrication of optoelectronic devices because of well-developed processing technology. However, the indirect band-gap makes it an inefficient material for optoelectronic devices. Over the years, various R&D efforts have focused on tailoring the optical function of Si to realize Si-based optoelectronics. The achievement of efficient room temperature light emission from the crystalline silicon is a major step towards the achievement of fully Si-based optoelectronics.

The fabrication of stable and reliable optoelectronic devices requires Si nanocrystals with high photoluminescence (PL) and electroluminescence (EL) quantum efficiency. One approach that is being actively pursued for integrated optoelectronic devices is the fabrication of SiOₓ (x≦2) thin films with embedded Si nanocrystals. The luminescence due to recombination of the electron-hole pairs confined in Si nanocrystals depends strongly on the nanocrystal size. The electrical and optical properties of the nanocrystalline Si embedded SiOₓ thin films depend on the size, concentration, and distribution of the Si nanocrystals. Various thin-film deposition techniques such as sputtering and plasma-enhanced chemical vapor deposition (PECVD), employing capacitively-coupled plasma source, are being investigated for the fabrication of stable and reliable nanocrystalline Si thin films.

However, conventional PECVD and sputtering techniques have the limitations of low plasma density, inefficient power coupling to the plasma, low ion/neutral ratio, and uncontrolled bulk, and interface damage due to high ion bombardment energy. Therefore, the oxide films formed from a conventional capacitively-coupled plasma (CCP) generated plasma may create reliability issues due to the high bombardment energy of the impinging ionic species. It is important to control or minimize any plasma-induced bulk or interface damage. However, it is not possible to control the ion energy using radio frequency (RF) of CCP generated plasma. Any attempt to enhance the reaction kinetics by increasing the applied power results in increased bombardment of the deposited film, creating a poor quality films with a high defect concentration. Additionally, the low plasma density associated with these types of sources (˜1×10⁸-10⁹ cm⁻³) leads to limited reaction possibilities in the plasma and on the film surface, inefficient generation of active radicals for enhanced process kinetics, inefficient oxidation, and reduction of impurities at low thermal budgets, which limits their usefulness in the fabrication of low-temperature electronic devices.

A deposition process that offers a more extended processing range and enhanced plasma characteristics than conventional plasma-based techniques, such as sputtering, PECVD, etc., is required to generate and control the particle size for PL and electroluminescent (EL) based device development. A process that can enhance plasma density and minimize plasma bombardment will ensure the growth of high quality films without plasma-induced microstructural damage. A process that can offer the possibility of controlling the interface and bulk quality of the films independently will enable the fabrication of high performance and high reliability electronic devices. A plasma process that can efficiently generate the active plasma species, radicals and ions, will enable noble thin film development with controlled process and property control.

For the fabrication of high quality SiOx thin films, the oxidation of a grown film is also critical to ensure high quality insulating layer across the nanocrystalline Si particles. A process that can generate active oxygen radicals at high concentrations will ensure the effective passivation of the Si nanoparticles in the oxide matrix surrounding it. A plasma process that can minimize plasma-induced damage will enable the formation of a high quality interface that is critical for the fabrication of high quality devices. Low thermal budget efficient oxidation and hydrogenation processes are critical and will be significant for the processing of high quality optoelectronic devices. The higher temperature thermal processes can interfere with the other device layers and they are not suitable in terms of efficiency and thermal budget, due to the lower reactivity of the thermally activated species. Additionally, a plasma process which can provide a more complete solution and capability in terms of growth/deposition of novel film structures, oxidation, hydrogenation, particle size creation and control, and independent control of plasma density and ion energy, and large area processing is desired for the development of high performance optoelectronic devices. Also, it is important to correlate the plasma process with the thin film properties as the various plasma parameters dictate the thin film properties and the desired film quality depends on the target application. Some of the key plasma and thin-film characteristics that depend on the target application are deposition rate, temperature, thermal budget, density, microstructure, interface quality, impurities, plasma-induced damage, state of the plasma generated active species (radicals/ions), plasma potential, process and system scaling, and electrical quality and reliability. A correlation among these parameters is critical to evaluate the film quality as the process map will dictate the film quality for the target application. It may not be possible to learn or develop thin-films by just extending the processes developed in low density plasma or other high-density plasma systems, as the plasma energy, composition (radical to ions), plasma potential, electron temperature, and thermal conditions correlate differently depending on the process map.

Low temperatures are generally desirable in liquid crystal display (LCD) manufacture, where large-scale devices are formed on transparent glass, quartz, or plastic substrate. These transparent substrates can be damaged when exposed to temperatures exceeding 650 degrees C. To address this temperature issue, low-temperature Si oxidation processes have been developed. These processes use a high-density plasma source such as an inductively coupled plasma (ICP) source, and are able to form Si oxide with a quality comparable to 1200 degree C. thermal oxidation methods.

It would be advantageous if the advantages realized with high-density plasma Si-containing films could be used to fabricate optical filters.

### SUMMARY OF THE INVENTION

The present invention describes the processing of Si rich SiOₓ thin films with a wide range of refractive index, suitable for diverse electronic applications. For example, SiOₓ thin films with refractive index values in the range of 1.46-3 can be fabricated by varying HDP process parameters. The high density plasma processed SiOₓ thin films show appreciable PL intensity in the visible range, which increases significantly after post-deposition annealing, indicating the formation of large concentration of Si nanocrystals. It was possible to control the refractive index by varying the radio frequency (RF) power and the deposition temperature. The observed optical response of the HDP processed SiOₓ thin films show the potential of the HDP processed Si rich SiOₓ thin films for diverse integrated optoelectronic applications.

Accordingly, a non-stoichiometric SiO_{X}N_{Y} thin-film optical filter is provided. The filter is formed from a substrate and a first non-stoichiometric SiO_{X1}N_{Y1} thin-film overlying the substrate, where (X1+Y1≦2 and Y1>0). The first non-stoichiometric SiO_{X1}N_{Y1} thin-film has a refractive index (n1) in the range of about 1.46 to 3, and complex refractive index (N1=n1+ik1), where k1 is an extinction coefficient in a range of about 0 to 0.5. The first non-stoichiometric SiO_{X1}N_{Y1} thin-film may be either intrinsic or doped. In one aspect, the first non-stoichiometric SiO_{X1}N_{Y1} thin-film has Si nanoparticles with a size in the range of about 1 to 10 nm.

In one variation, a second non-stoichiometric SiO_{X2}N_{Y2} thin-film overlies the first non-stoichiometric SiO_{X1}N_{Y1} thin-film, where Y1≠Y2. Again, the second non-stoichiometric SiO_{X1}N_{Y1} thin-film may be intrinsic and doped. In another variation, a stoichiometric SiO_{X2}N_{Y2} thin-film, intrinsic or doped, overlies the first non-stoichiometric SiO_{X1}N_{Y1} thin-film.

In one aspect, the first non-stoichiometric SiO_{X1}N_{Y1} thin-film has a graded first refractive index (n1). The grading function may be continuous, stepped, or cyclic. For example, the first non-stoichiometric SiO_{X}N_{Y} thin-film may have a graded refractive index with a Y1 value that varies with the distance of the film from the substrate.

Additional details of the above-described optical filter are presented below.

### BRIEF DESCRIPTION OF THE DRAWINGS

FIGS. 1A through 1F depict some fundamental optical characteristics (prior art).

FIGS. 2A through 2I depict some typical waveguide configurations (prior art).

FIGS. 3A and 3B depict typical waveguide structures, illustrating the use of single or multilayer structures to control light guiding and wavelength conversion (prior art).

FIG. 4 is a schematic drawing of a high-density plasma (HDP) system with an inductively coupled plasma source.

FIGS. 5A and 5B illustrate some optical dispersion characteristics of nc-Si embedded SiOₓ thin films.

FIGS. 6A through 6C illustrate the PL spectrum of some HDP processed nc-Si embedded SiOₓ thin films covering the visible part of the spectrum.

FIG. 7 is a partial cross-sectional view of a non-stoichiometric SiO_{X}N_{Y} thin-film optical filter.

FIG. 8 is a partial cross-sectional view of a first variation of the non-stoichiometric SiO_{X}N_{Y} thin-film optical filter of FIG. 7.

FIG. 9 is a partial cross-sectional view of a second variation of the non-stoichiometric SiO_{X}N_{Y} thin-film optical filter of FIG. 7.

FIGS. 10A through 10C are partial cross-sectional views of a third variation of the first non-stoichiometric SiO_{X1}N_{Y1} thin-film of FIG. 7 with a graded first refractive index (n1).

FIG. 11 is a partial cross-sectional view of a fourth variation of the non-stoichiometric SiO_{X}N_{Y} thin-film optical filter of FIG. 7.

FIG. 12 is a partial cross-sectional view of a fifth variation of the non-stoichiometric SiO_{X}N_{Y} thin-film optical filter of FIG. 7.

FIG. 13 is a partial cross-sectional view depicting of a variation of the optical filter of FIG. 12.

FIG. 14 is a partial cross-sectional view of a sixth variation of the non-stoichiometric SiO_{X}N_{Y} thin-film optical filter of FIG. 7.

FIG. 15 is a partial cross-sectional view depicting of a variation of the optical filter of FIG. 14.

FIG. 16 is a partial cross-sectional view of a seventh variation of the non-stoichiometric SiO_{X}N_{Y} thin-film optical filter of FIG. 7.

FIG. 17 is a partial cross-sectional view of an eighth variation of the non-stoichiometric SiO_{X}N_{Y} thin-film optical filter of FIG. 7.

FIG. 18 is a partial cross sectional view depicting an alternate representation of the optical filter grating variation presented in FIG. 16.

### DETAILED DESCRIPTION

The present invention describes a high density plasma technique for the fabrication of stoichiometric and nc-Si embedded SiO_{X}N_{Y} (X+Y<2 and Y>0) thin films for novel optical devices. The HDP plasma processed nc-Si embedded SiOₓ thin films show a wide optical dispersion depending on the processing conditions. It is possible to vary the refractive index and the extinction constant of the films in the range of 1.46-3 and 0-0.5, respectively; which overlaps the optical characteristics of many conventional dielectric and semiconductor materials currently used in the fabrication of optical devices. In addition, the HDP plasma process enables the independent control of the n and k values, which can be successfully exploited for the fabrication of devices with wide process margins, and a significant reduction in process complexity and cost.

One new concept that also emerges from the nc-Si containing films is that of wavelength conversion. The nc-Si particle size dictates the wavelength tuning and a nc-Si particle containing medium can be used for the light intensity enhancement (active medium for light guiding), wavelength conversion (PL/EL response), and converting a broad incident spectrum into a narrow band for novel optoelectronic devices.

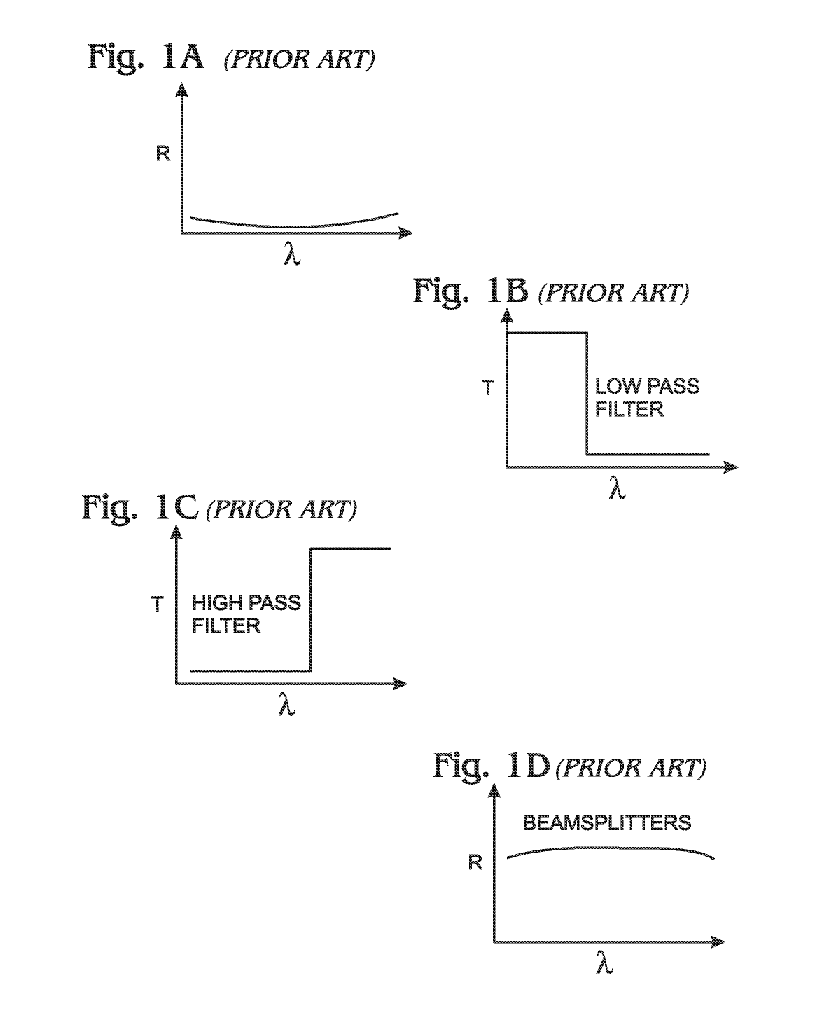

FIGS. 1A through 1F depict some fundamental optical characteristics (prior art). FIGS. 1B, 1C, and 1E plot transmission (T) as a function of light wavelength (λ), depicting low pass, high pass, and bandpass filters, respectively. FIGS. 1A and 1D plot reflection as a function of light wavelength. FIG. 1A depicts the characteristics of a typical anti-reflective coating. In FIG. 1D, the film partially reflects and partially transmits incident light. Optical devices can be grouped into two major categories based upon their application: devices in which the light travels parallel to the plane of the substrate with the films acting as waveguide; and, devices in which the light travels perpendicular to the film plane for use as antireflection coating, filters, mirrors, beam splitters, etc. The selection of the thin film material depends on the desired optical effect. A single or multilayer thin film structure is typically required to get the desired optical characteristics. The main thin film characteristics that are critical for optical applications are the reflection, transmission, absorption, and spectral response. The selection of the fabrication technique, deposition process, and the process temperature strongly influence the optical characteristics of thin films. In addition the bulk and interface characteristics of various layers in multi-layer structures dictate the overall performance of the optical device.

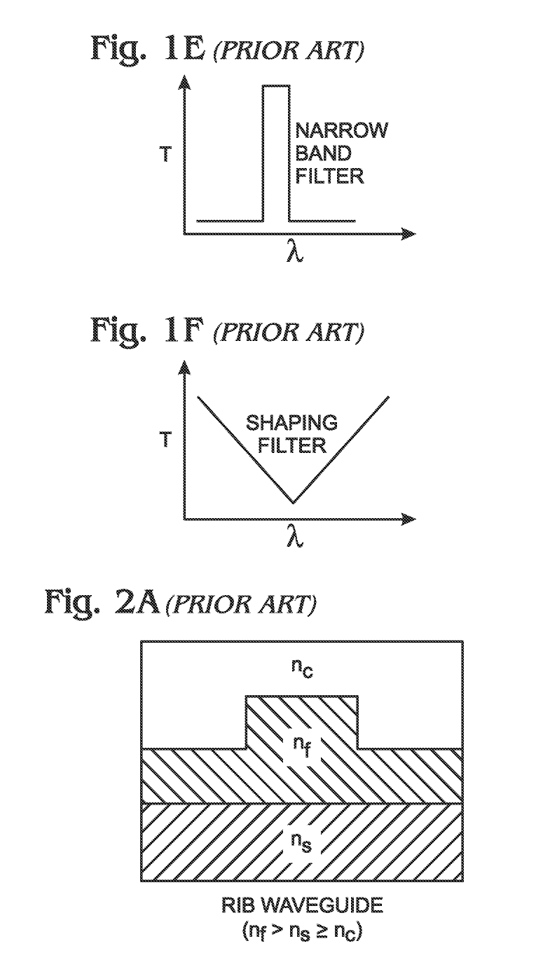

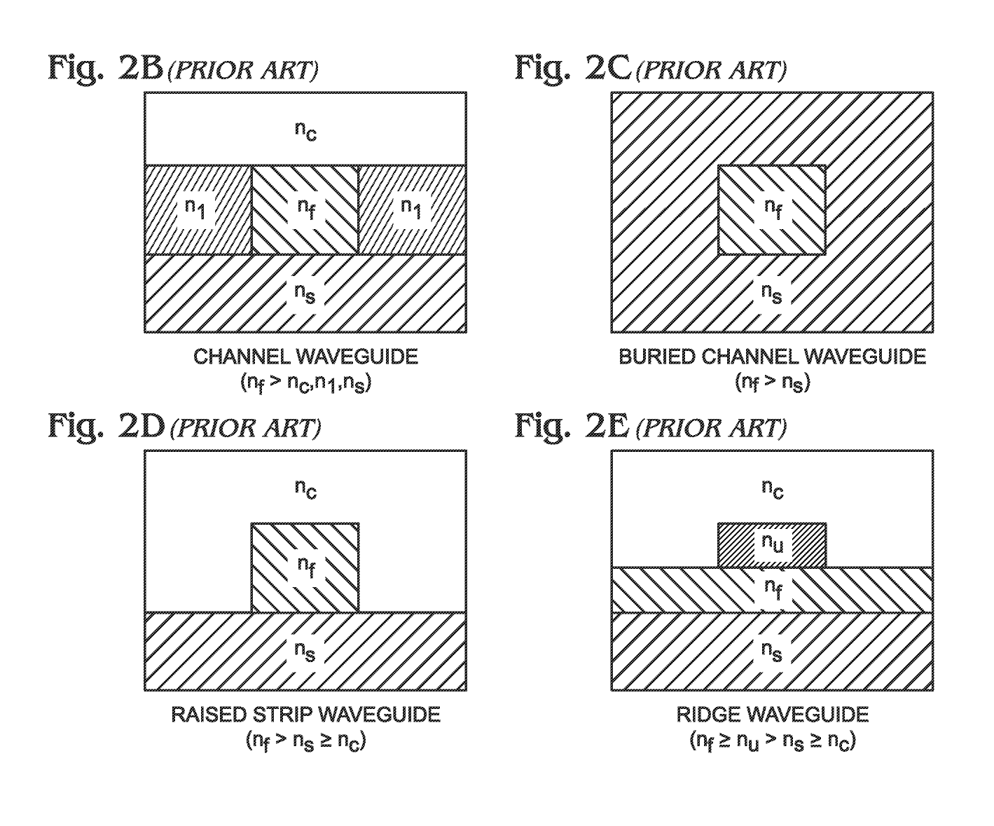

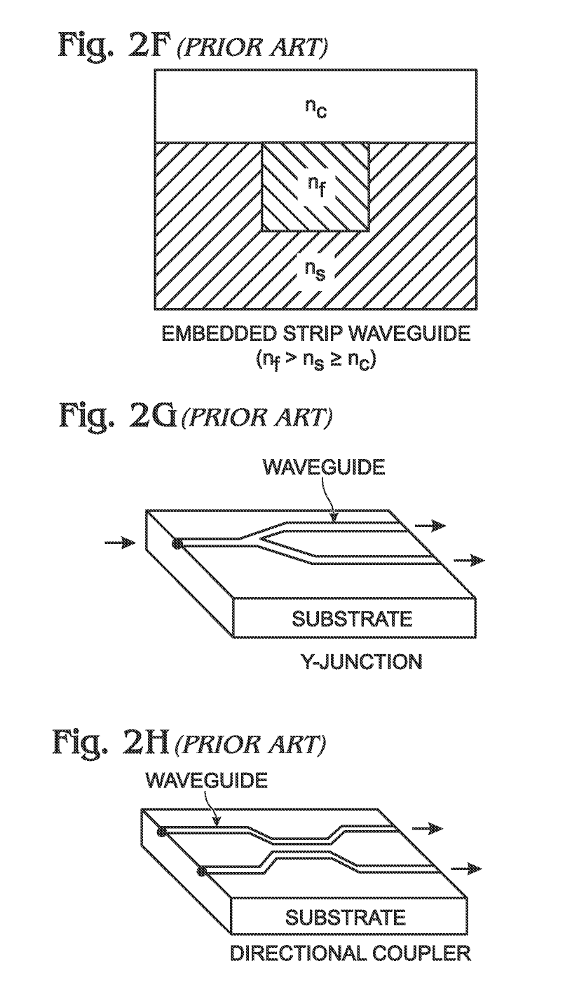

FIGS. 2A through 2I depict some typical waveguide configurations (prior art). Guided wave components are useful in routing optical signals on a chip and also for the functions of directional coupling, filtering, and modulation. The integration of the optical waveguides with the active components such as sources, detectors, modulators, etc., is useful in the realization of some high performance optical communication devices.

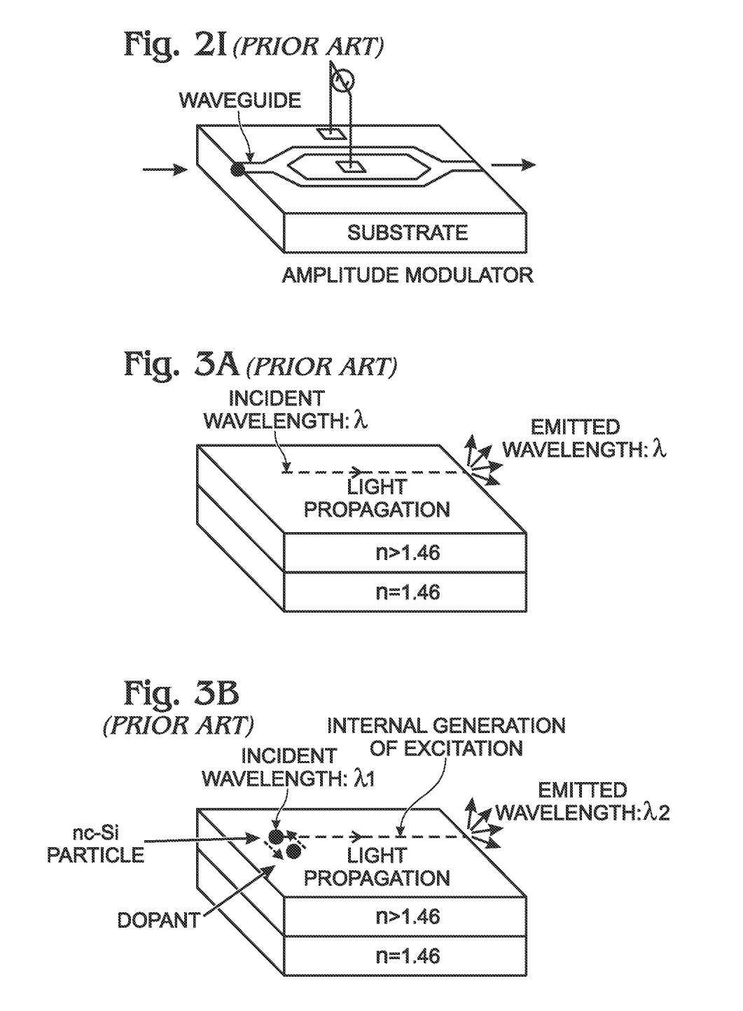

FIGS. 3A and 3B depict typical waveguide structures, illustrating the use of single or multilayer structures to control light guiding and wavelength conversion (prior art). In FIG. 3A, the intensity ratio Iout/Iin is dependent upon system losses. In FIG. 3B, the use of a nc-Si embedded SiOₓN_{y} (x+y≦2) thin film makes the intensity ratio dependent upon factors such as nc-Si particle excitation by the source, nc-Si particle excitation by source or dopant, dopant excitation by source or nc-Si emission, as well as system losses. The use of such a nc-Si embedded SiOₓN_{y} (x+y≦2) thin film permits control of optical dispersion over a wide range of values using a single material system and particle size control. For example, guided wavelength conversion and amplification can be controlled through nc-Si particle size control. Film doping can also be used to control the guided wavelength and signal amplification. The above-mentioned nc-Si embedded SiOₓN_{y} (x+y≦2) thin films can be integrated on diverse metallic, dielectric, and semiconductor substrates.

The selection of the thin films for optoelectronic applications depends on the optical, electrical, mechanical, and chemical properties. The selection of the fabrication technique and deposition process is equally important for the fabrication of high quality thin films. Various thin film characteristics such as microstructure, grain size, composition, density, defects and impurities, structural homogeneity, and interfacial characteristics are strongly influenced by the deposition technique and process parameters.

This invention describes optical devices fabricated using the high density plasma processing of stoichiometric and nc-Si embedded SiOₓN_{y} (x+y≦2) thin films for novel optical devices. As used herein, a nc-Si embedded SiOₓN_{y} (x+y≦2) thin film is also referred to as a non-stoichiometric SiO_{X}N_{Y} thin-film, where (X+Y≦2 and Y>0). A non-stoichiometric SiO_{X}N_{Y} thin-film, as used herein, is understood to be a film with nanocrystalline (nc) Si particles, and may also be referred to as a Si-rich SiO_{X}N_{Y} thin-film. The term “non-stoichiometric” as used herein retains the meaning conventionally understood in the art as a chemical compound with an elemental composition that cannot be represented by a ratio of well-defined natural numbers and is, therefore, in violation of the law of definite proportions. Conventionally, a non-stoichiometric compound is a solid that is understood to include random defects, resulting in the deficiency of one element. Since the compound needs to be overall electrically neutral, the missing atom's charge requires compensation in the charge for another atom in the compound, by either changing the oxidation state, or by replacing it with an atom of a different element with a different charge. More particularly, the “defect” in a non-stoichiometric SiO_{X}N_{Y} involves nanocrystalline particles.

The HDP technique is suitable for the fabrication of high quality thin films due to high plasma density, low plasma potential, and independent control of plasma energy and density. The HDP technique is also attractive for the fabrication high quality films with minimal process or system induced impurity content. The HDP processed films exhibit superior bulk and interfacial characteristics due to minimal plasma induced structural damage and process-induced impurities, as compared to conventional plasma based deposition techniques such sputtering, ion beam deposition, capacitively-coupled plasma (CCP) source based PECVD, and hot-wire CVD. The present invention describes a novel HDP process for the creation of nano-Si particles in SiO_{X}N_{Y} films in the as-deposited state. The nc-Si particle concentration can be further enhanced by post-deposition annealing and defect passivation treatments. The HDP processed nc-Si embedded SiO_{X}N_{Y} films have tunable optical dispersion characteristics which can be exploited for the fabrication of optoelectronic devices.

Another significant aspect of the nc-Si embedded SiO_{X}N_{Y} films is significant PL emission in the visible part of the spectrum, which can be used for the fabrication of active optical devices exhibiting signal gain and wavelength tuning. The optical characteristics of the HDP processed thin films can be further tuned by doping suitable impurities to control the optical response extending on either side of the visible spectrum, i.e., deep UV to far IR. The HDP technique is also suitable for low temperature and low thermal budget defect passivation of the films for enhanced electrical and optical response.

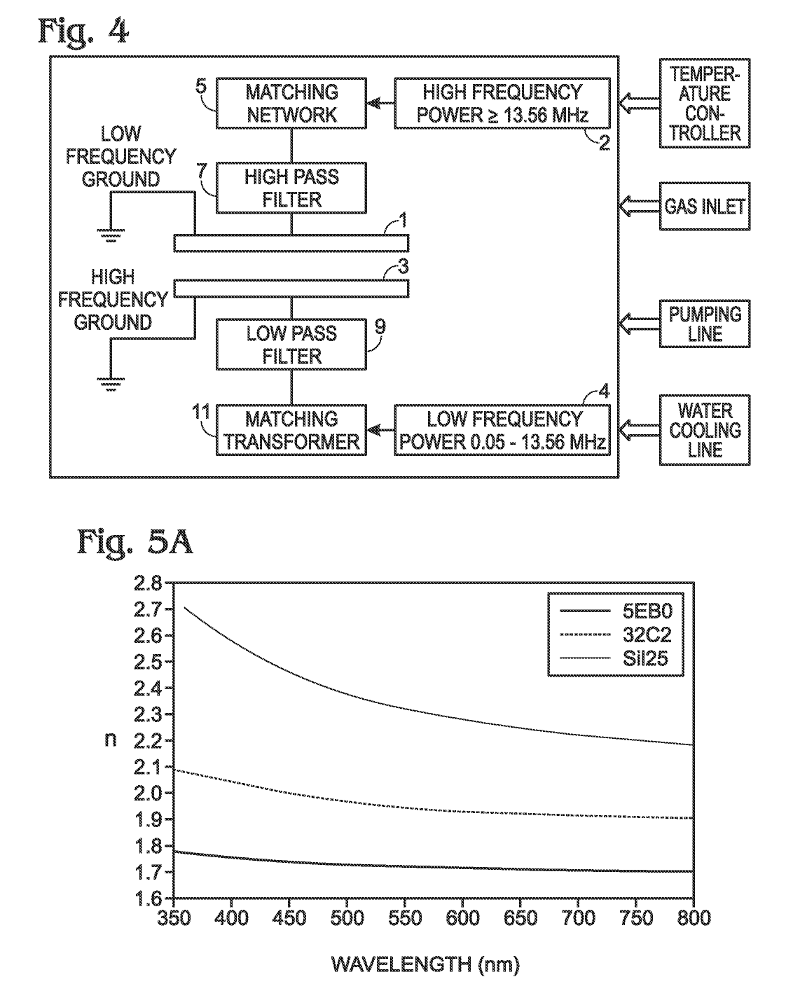

FIG. 4 is a schematic drawing of a high-density plasma (HDP) system with an inductively coupled plasma source. The top electrode 1 is driven by a high frequency radio frequency (RF) source 2, while the bottom electrode 3 is driven by a lower frequency power source 4. The RF power is coupled to the top electrode 1, from the high-density inductively coupled plasma (ICP) source 2, through a matching network 5 and high pass filter 7. The power to the bottom electrode 3, through a low pass filter 9 and matching transformer 11, can be varied independently of the top electrode 1. The top electrode power frequency can be in the range of about 13.56 to about 300 megahertz (MHz) depending on the ICP design. The bottom electrode power frequency can be varied in the range of about 50 kilohertz (KHz) to about 13.56 MHz, to control the ion energy. The pressure can be varied up to 500 mTorr. The top electrode power can be as great as about 10 watts per square-centimeter (W/cm²), while the bottom electrode power can be as great as about 3 W/cm².

One interesting feature of the HDP system is that there are no inductive coils exposed to the plasma, which eliminates any source-induced impurities. The power to the top and bottom electrodes can be controlled independently. There is no need to adjust the system body potential using a variable capacitor, as the electrodes are not exposed to the plasma. That is, there is no crosstalk between the top and bottom electrode powers, and the plasma potential is low, typically less than 20 V. System body potential is a floating type of potential, dependent on the system design and the nature of the power coupling.

The HDP tool is a true high-density plasma process with an electron concentration of greater than 1×10¹¹ cm⁻³, and the electron temperature is less than 10 eV. There is no need to maintain a bias differential between the capacitor connected to the top electrode and the system body, as in many high-density plasma systems and conventional designs such as capacitively-coupled plasma tools. Alternately stated, both the top and bottom electrodes receive RF and low frequency (LF) powers.

High quality stoichiometric SiOₓN_{y} (x+y=2) and nc-Si embedded SiOₓN_{y} (x+y<2) thin films can be processed by HDP techniques at process temperatures below 400° C. Some of the substrates that are suitable for integrated optical devices are Si, Ge, Glass. Quartz, SiC, GaN, SiₓGe₁₋ₓ. The HDP processed films can be doped in-situ by adding a dopant source gas or incorporating physical sputtering source in the chamber along with the high-density PECVD setup. The optical properties of the HDP processed films can also be modified by implanting dopant species. Some typical process conditions for the fabrication of stoichiometric SiOₓN_{y} (x+y=2) and nc-Si embedded SiOₓN_{y} (x+y<2) thin films by HD-PECVD technique are listed in Table 1.

TABLE 1
High-density plasma deposition of stoichiometric SiOₓN_{y} (x + y =
2) and nc-Si embedded SiOₓN_{y} (x + y < 2) thin films

| | |
|---|---|
| Top Electrode Power | 13.56-300 MHz, up to 10 W/cm², |
| Bottom Electrode | 50 KHz-13.56 MHz, up to 3 W/cm² |
| Power | |
| Pressure | 1-500 mTorr |
| Si source | Any suitable Si precursor |
| | (SiH₄, Si₂H₆, TEOS, etc.) e.g.: SiH₄ |
| Oxygen Source | Any suitable source of oxygen: |
| | (O₂, O₃, NO, etc.) e.g.: N₂O, O₂ |
| Nitrogen Source | Any suitable source of nitrogen |
| | (NH₃, N₂, etc.) e.g.: N₂ |
| Inert Gases ion | Any suitable inert gas: |
| the plasma | Noble gases, N₂, etc. |
| nc-Si particle | nc-Si particles: Silicon |
| creation and | source + Oxygen source + |
| defect passivation | inert gases + H₂ |
| | Passivation: Source of |
| | hydrogen (NH₃, H₂, etc.) |
| Temperature | 25-400° C. |

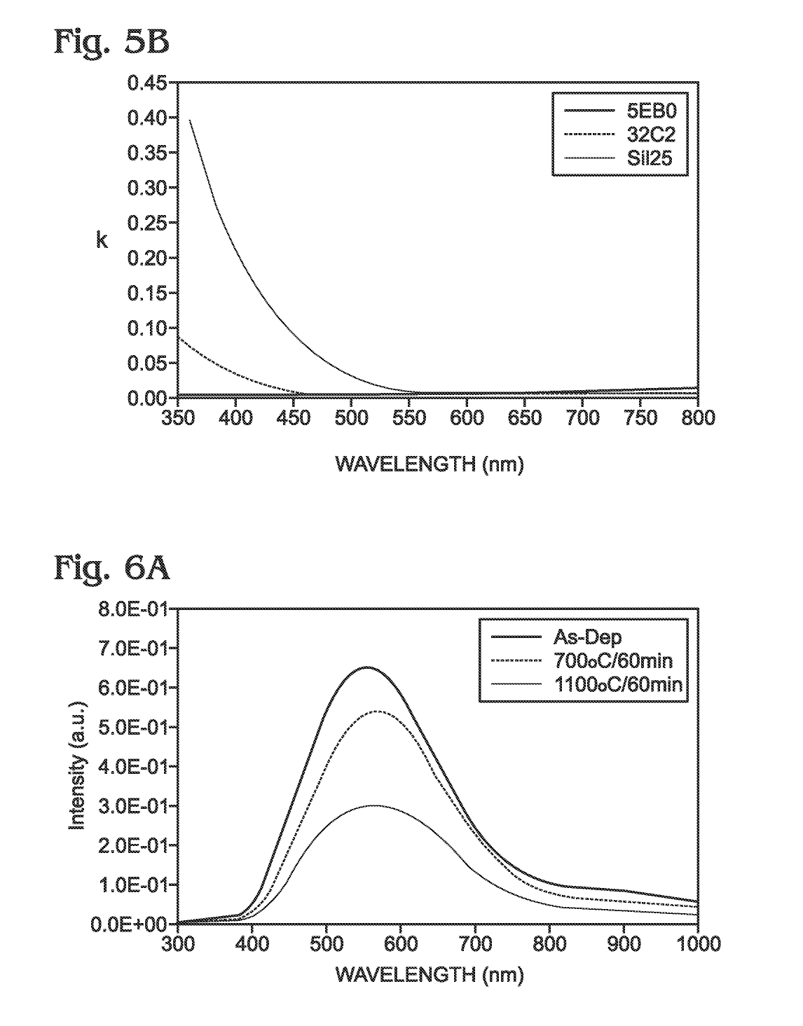

FIGS. 5A and 5B illustrate some optical dispersion characteristics of nc-Si embedded SiOₓ thin films. It is possible to tune the refractive index and the extinction coefficient of the films independently. The independent control of the n and k values enables a better control of the optical transmission, reflection, and absorption characteristics for the design of novel optical and optoelectronic devices. The optical absorption edge of the films can also be effectively controlled by varying the thin film composition and the nc-Si particle size. The combination of the n, k dispersion, absorption edge, and PL/EL emission characteristics can be exploited for the fabrication of novel optical and optoelectronic devices with controlled optical response characteristics.

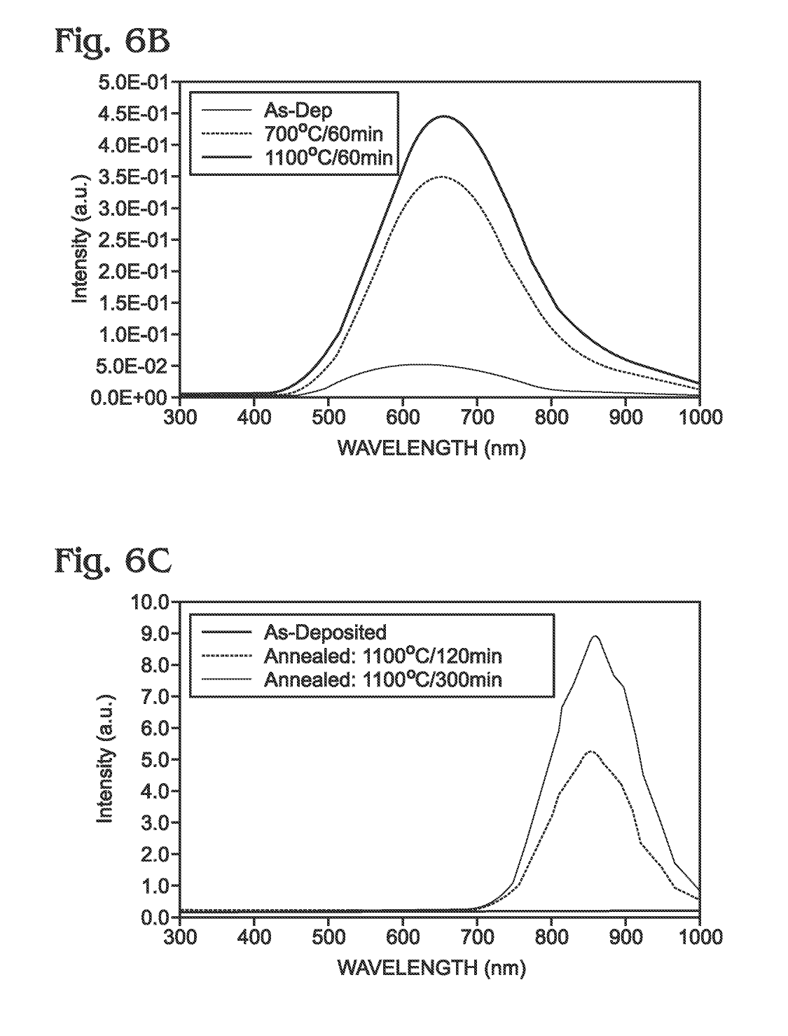

FIGS. 6A through 6C illustrate the PL spectrum of some HDP processed nc-Si embedded SiOₓ thin films covering the visible part of the spectrum. The emitted wavelength depends strongly on the particle size. The HDP plasma process is efficient in the controlling the particle size over a wide range covering the entire visible spectrum. The HDP process is effective in the creation of the nc-Si particles at a low process temperature of 300° C., as is evident in the appreciable PL signal. The PL emission intensity is significantly enhanced by post-deposition annealing treatment at higher temperatures, which is due to phase separation and quantum confinement effects. Additionally, the HDP technique is suitable for the low temperature and low thermal budget defect passivation.

To summarize, single or multilayer structures can be made using the above-described nc-Si embedded SiOₓN_{y} (x+y<2) thin films, with control over n, k, and wavelength emission in terms of film composition, annealing treatment, passivation, and nc-particle size control. Active waveguides can be formed capable of wavelength conversion and narrowing down the wavelength spectrum. Group IV, rare earth dopants can be added to the films for wavelength control. Optical gain and birefringence can be exploited for optoelectronic applications. Enhanced optical emission control over the emitted wavelength can be obtained by doping. The nc-Si embedded SiOₓN_{y} (x+y<2) thin films can be used with a wide range of other materials. For example, optical wave-guides can be integrated with PIN diode detectors. Also, nc-Si embedded thin films can be integrated with wide band-gap semiconductors or phosphors for enhanced light emission and control. Additional details of the fabrication processes can be found in a related pending patent application entitled, HIGH DENSITY PLASMA STOICHIOMETRIC SiOxNy FILMS, invented by Pooran Joshi et al., Ser. No. 11/698,623, filed on Jan. 26, 2007, Attorney Docket No. SLA8117, which is incorporated herein by reference.

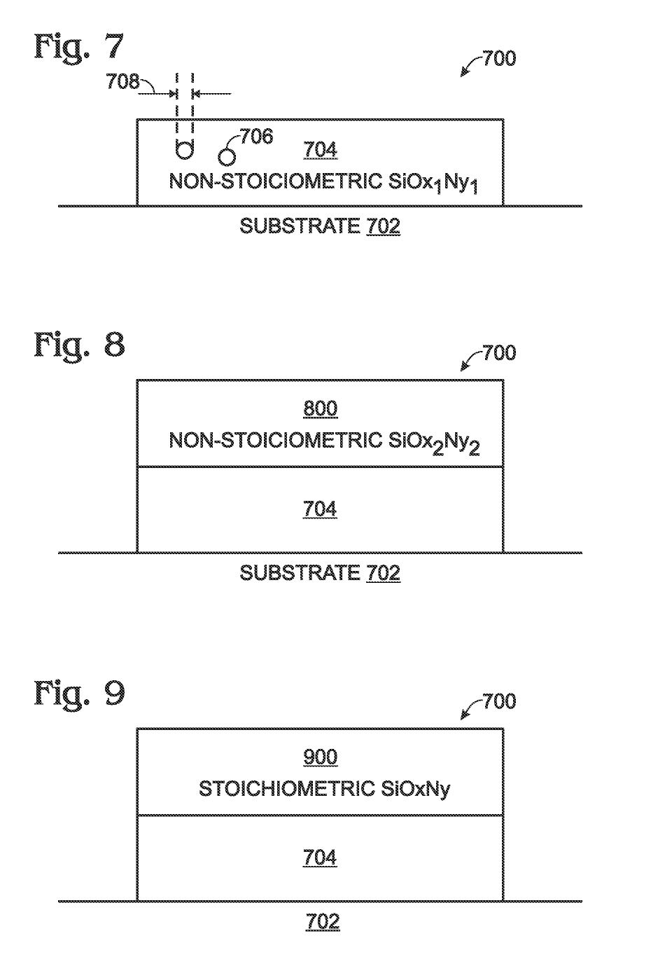

FIG. 7 is a partial cross-sectional view of a non-stoichiometric SiO_{X}N_{Y} thin-film optical filter. As used herein, an optical filter is understood to be a device that changes at least one characteristic of incident light. A filter may be transmissive, reflective, and act as a waveguide. The filter 700 comprises a substrate 702 and a first non-stoichiometric SiO_{X1}N_{Y1} thin-film 704 overlying the substrate 702, where (X1+Y1<2 and Y1>0). The first non-stoichiometric SiO_{X1}N_{Y1} thin-film 704 has a refractive index (n1) in the range of about 1.46 to 3, and complex refractive index (N1=n1+ik1), where k1 is an extinction coefficient in a range of about 0 to 0.5. The substrate 702 may be a material such as plastic, glass, quartz, ceramic, metal, polymer, undoped Si, doped Si, SiC, Ge, Si₁₋ₓGeₓ, InGaAs, GaN, GaP, Si-on-insulator (SOI), Ge-on-insulator (GOI), silicon-containing materials, or semiconductor materials. However, the filter is not necessarily limited to just this list of example substrate materials.

The first non-stoichiometric SiO_{X1}N_{Y1} thin-film 704 may be either intrinsic or doped. For example, the dopant may be a Type 3, Type 4, Type 5, or rare earth elements. In other aspects, the film 704 may be doped with a combination of elements, or doped with elements not presented in the list of examples.

In one aspect, the first non-stoichiometric SiO_{X1}N_{Y1} thin-film 704 includes Si nanoparticles 706 having a size (e.g., a diameter) in a range of about 1 to 10 nanometers (nm).

FIG. 8 is a partial cross-sectional view of a first variation of the non-stoichiometric SiO_{X}N_{Y} thin-film optical filter of FIG. 7. A second non-stoichiometric SiO_{X2}N_{Y2} thin-film 800 overlies the first non-stoichiometric SiO_{X1}N_{Y1} thin-film 704, where Y1≠Y2. The second non-stoichiometric SiO_{X1}N_{Y1} thin-films may be either intrinsic or doped, as described above with respect to film 704.

FIG. 9 is a partial cross-sectional view of a second variation of the non-stoichiometric SiO_{X}N_{Y} thin-film optical filter of FIG. 7. A stoichiometric SiO_{X2}N_{Y2} thin-film 900 overlies the first non-stoichiometric SiO_{X1}N_{Y1} thin-film 704. The stoichiometric SiO_{X2}N_{Y2} thin-film 900 may be either intrinsic or doped. Some examples of dopants are mentioned above in the description of film 704.

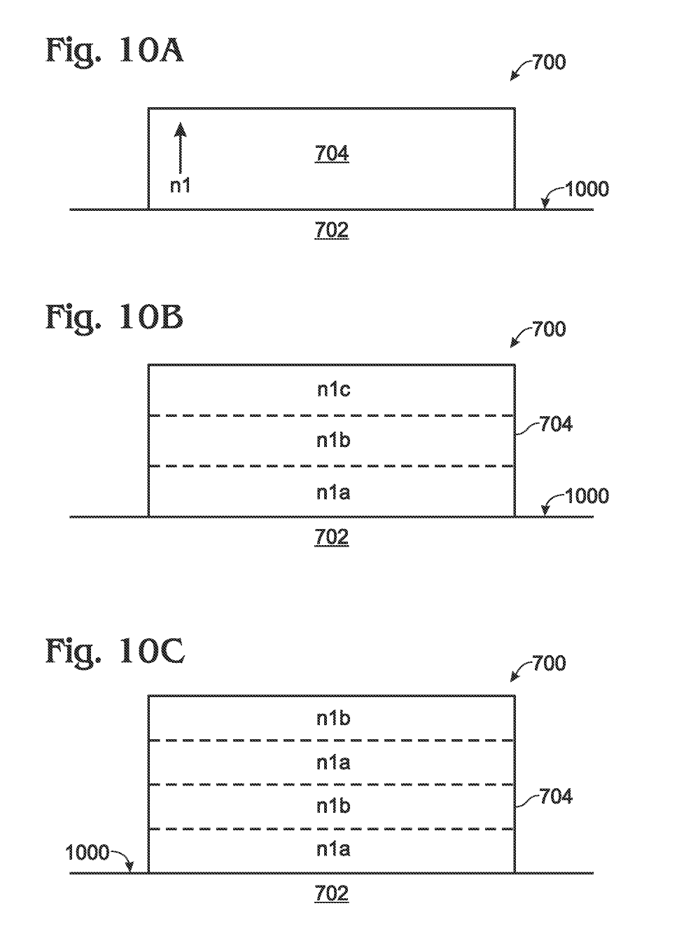

FIGS. 10A through 10C are partial cross-sectional views of a third variation of the first non-stoichiometric SiO_{X1}N_{Y1} thin-film of FIG. 7 with a graded first refractive index (n1). For example, the first non-stoichiometric SiO_{X}N_{Y} thin-film 704 may have a graded refractive index with a Y1 value that varies with the distance of the film from the substrate surface 1000. In FIG. 10A, the non-stoichiometric SiO_{X}N_{Y} thin-film 704 has a graded refractive index described as a continuous function. As shown, the value n1 increases as the distance from the substrate surface 1000 increases. Alternately but not shown, the value of n1 may decrease with the distance from surface 1000. FIG. 10B depicts the non-stoichiometric SiO_{X}N_{Y} thin-film 704 with a stepped graded refractive index. For example, n1a>n1b>n1c. FIG. 10B depicts the non-stoichiometric SiO_{X}N_{Y} thin-film 704 with a cyclic graded refractive index. For example, n1a>n1b, iteratively repeated. Shown is a cycle of 2 iterations, with 2 steps per iteration. However, the filter is not limited to any particular number of steps per iteration, or any particular number of iterations.

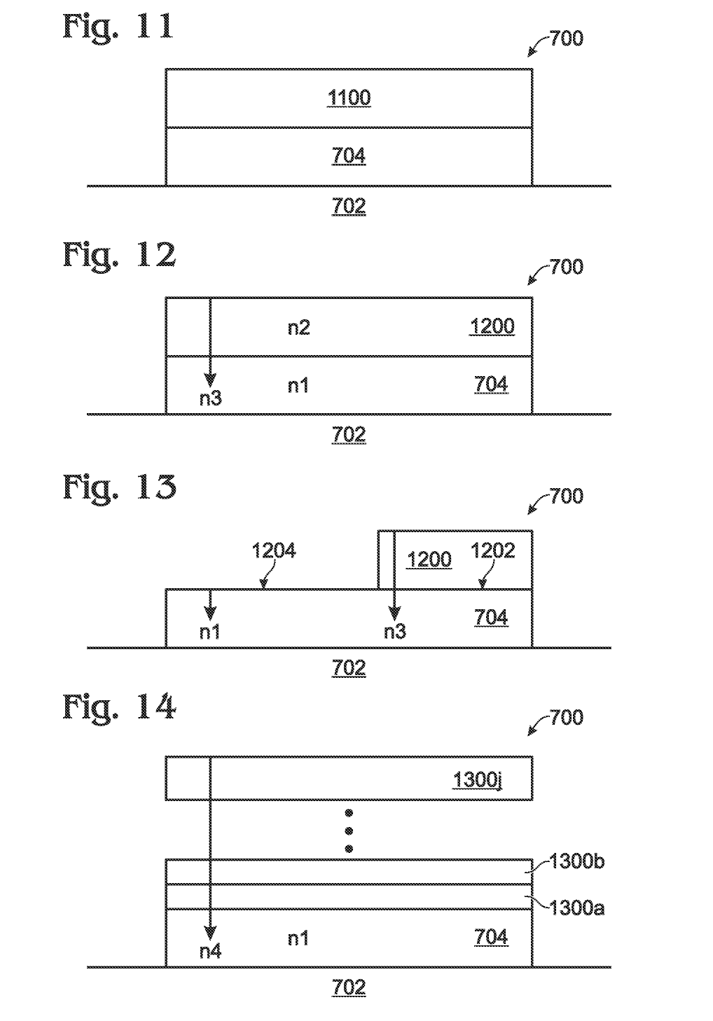

FIG. 11 is a partial cross-sectional view of a fourth variation of the non-stoichiometric SiO_{X}N_{Y} thin-film optical filter of FIG. 7. More generally, a thin-film 1100 may overlie the first non-stoichiometric SiO_{X1}N_{Y1}, thin-film 704, made from a material other than SiO_{X}N_{Y}. For example film 1100 may be a dielectric, semiconductor, organic thin-film, polymer, undoped Si, doped Si, amorphous Si, polycrystalline Si, single-crystal Si, SiC, Ge, amorphous Si₁₋ₓGeₓ, polycrystalline Si₁₋ₓGeₓ, or single-crystal Si₁₋ₓGeₓ, to name a few examples.

FIG. 12 is a partial cross-sectional view of a fifth variation of the non-stoichiometric SiO_{X}N_{Y} thin-film optical filter of FIG. 7. Regardless of the overlying film material, a second film layer 1200 overlying the first non-stoichiometric SiO_{X}N_{Y} thin-film 704 typically has a second refractive index (n2), different than the first refractive index (n1). In one aspect, the combination of the first non-stoichiometric SiO_{X1}N_{Y1} thin-film 704 and the second film 1200, has an overall third refractive index (n3).

FIG. 13 is a partial cross-sectional view depicting of a variation of the optical filter of FIG. 12. The second film 1200 covers a first area 1202 of the first non-stoichiometric SiO_{X}N_{Y} thin-film 704 and exposes a second area 1204 of the first non-stoichiometric SiO_{X}N_{Y} thin-film. The refractive index through the first area 1202 of the non-stoichiometric SiO_{X1}N_{Y1} thin-film and the overlying second film layer 1200 is the third refractive index. The refractive index through the second area 1204 of the non-stoichiometric SiO_{X1}N_{Y1} thin-film 704 is the first refractive index.

FIG. 14 is a partial cross-sectional view of a sixth variation of the non-stoichiometric SiO_{X}N_{Y} thin-film optical filter of FIG. 7. A plurality of films 1300a through 1300j overlie the first non-stoichiometric SiO_{X}N_{Y} thin-film 704. The combination of the first non-stoichiometric SiO_{X1}N_{Y1} thin-film 704 and the plurality of overlying film layers 1300a-1300n has an overall fourth refractive index (n4). Note, j is not necessarily limited to any particular number.

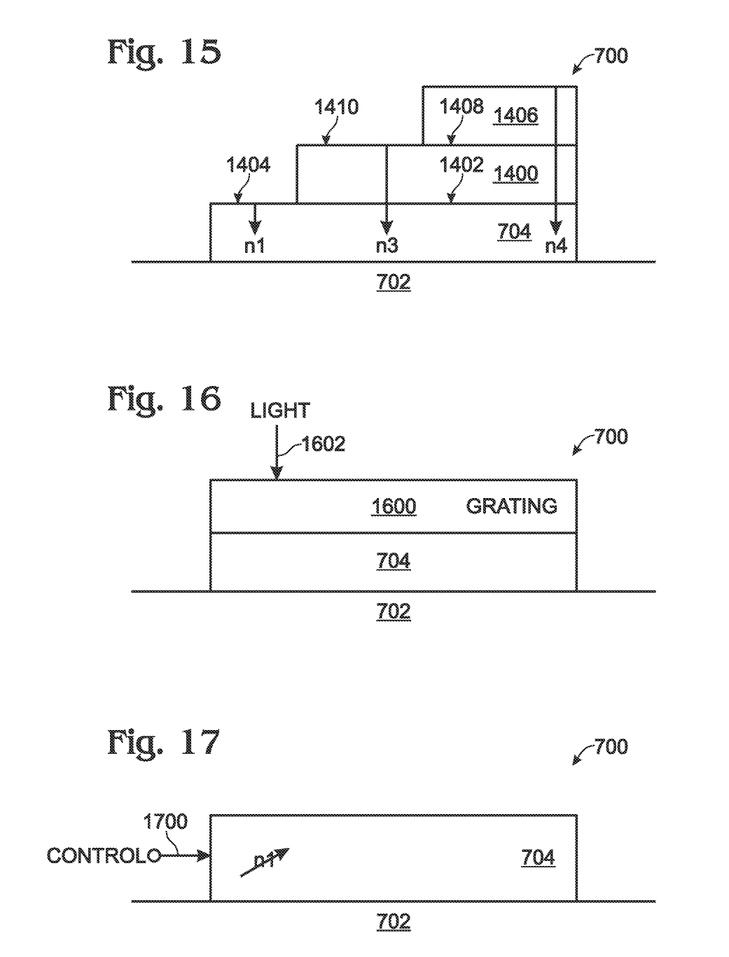

FIG. 15 is a partial cross-sectional view depicting of a first variation of the optical filter of FIG. 14. In this example, j=2. A second film 1400 covers a first area 1402 of the first non-stoichiometric SiO_{X}N_{Y} thin-film 704 and exposes a second area 1404 of the first non-stoichiometric SiO_{X}N_{Y} thin-film. A third film 1406 covers a first area 1408 of the second film 1400 and exposes a second area 1410 of the second film. The refractive index through the first area 1402 of the non-stoichiometric SiO_{X1}N_{Y1} thin-film, the first area 1408 of the second film, and the third film layer 1406 is the fourth refractive index. The refractive index through the first area 1402 of the non-stoichiometric SiO_{X1}N_{Y1} thin-film and the second area 1410 of the second film layer 1400 is the third refractive index. The refractive index through the second area 1404 of the non-stoichiometric SiO_{X1}N_{Y1} thin-film is the first refractive index. Although a 3-layer film example has been presented, the filter 700 is not limited to any particular number of films, or arrangement of film layers.

FIG. 16 is a partial cross-sectional view of a seventh variation of the non-stoichiometric SiO_{X}N_{Y} thin-film optical filter of FIG. 7. A grating 1600 overlies the first non-stoichiometric SiO_{X}N_{Y} thin-film 704. The grating 1600 has diffraction and reflection characteristics to control incident light 1602 introduced to the first non-stoichiometric SiO_{X}N_{Y} thin-film 704. In one aspect, the grating 1600 includes a phosphor material.

Phosphor materials are the materials which emit light when excited by charged particles or light. The emitted light spectrum depends on the material composition. While the filter 700 has the general function of controlling the transmission, absorption, and reflection characteristics of the incident light, a combination of a phosphor layer with the filter can provide enhanced control over the filter characteristics. Phosphor materials are commonly used in display-related applications, and are well known to those with skill in the art. As used herein, all photo-luminescent materials are phosphor materials.

The grating 1600 is a structure that can control the characteristics of the incident light. As a result, the light that is coupled to the underlying film 704 is dependent upon the grating characteristics. As with the filter 700 in general, the grating 1600 can be configured in many different ways from a diverse family of thin-film materials. In general, the diffraction and reflection characteristics define the grating. Although the grating structure 1600 is shown overlying film 704 in this figure, it can alternately be positioned between film 704 and the substrate 702 (not shown), or positioned amongst a plurality of film layers overlying film 704 (not shown).

In one aspect, a diffraction grating is a reflecting or transparent element, whose optical properties are periodically modulated. The diffraction gratings 1600 can be realized as fine parallel and equally spaced grooves or rulings on material surface. When light is incident on a diffraction grating, diffractive and mutual interference effects occur, and light is reflected or transmitted in discrete directions, called diffraction orders.

FIG. 17 is a partial cross-sectional view of an eighth variation of the non-stoichiometric SiO_{X}N_{Y} thin-film optical filter of FIG. 7. In this aspect, the first non-stoichiometric SiO_{X1}N_{Y1} thin-film 704 has a tunable refractive index. The first non-stoichiometric SiO_{X1}N_{Y1} thin-film 704 has a refractive index tunable to an extrinsic environmental condition, represented by reference designator 1700, such as temperature, electric field, light, or pressure.

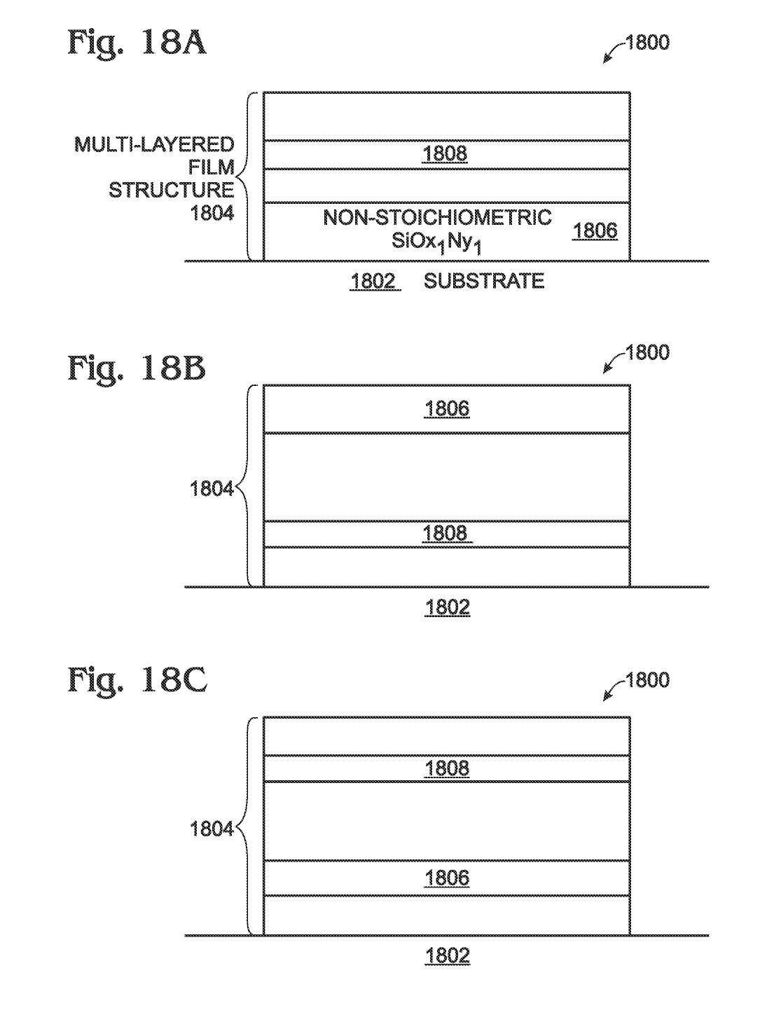

FIGS. 18A through 18C are partial cross sectional views depicting an alternate representation of the optical filter grating variation presented in FIG. 16. The non-stoichiometric SiO_{X}N_{Y} thin-film optical filter 1800 comprises a substrate 1802 and a multilayered film structure 1804 overlying the substrate 1802. The multilayered film structure 1804 includes a non-stoichiometric SiO_{X1}N_{Y1} thin-film, where (X1+Y1<2 and Y1>0). The non-stoichiometric SiO_{X1}N_{Y1} thin-film 1806 has a refractive index (n1) in the range of about 1.46 to 3, and complex refractive index (N1=n1+ik1), where k1 is an extinction coefficient in a range of about 0 to 0.5. The multilayered film structure 1804 also includes a film 1808 having diffraction and reflection characteristics to control incident light. Film 1808 may be a diffraction grating, a phosphor material film, or a phosphor-containing grating.

In FIG. 18A, film 1808 is embedded between other films in the multilayered film structure 1804, overlying the non-stoichiometric SiO_{X1}N_{Y1} thin-film 1806. In FIG. 18B, film 1808 is embedded between other films in the multilayered film structure 1804, underlying the non-stoichiometric SiO_{X1}N_{Y1} thin-film 1806. In FIG. 18C, film 1808 and film 1806 are both embedded between other films in the multilayered film structure 1804, with film 1808 overlying the non-stoichiometric SiO_{X1}N_{Y1} thin-film 1806. Other combinations of multilayered film structures would also be possible. Other films in the structure 1804 may include dielectrics, semiconductors, organic thin-films, polymer, undoped Si, doped Si, amorphous Si, polycrystalline Si, single-crystal Si, SiC, Ge, amorphous Si₁₋ₓGeₓ, polycrystalline Si₁₋ₓGeₓ, single-crystal Si₁₋ₓGeₓ, stoichiometric SiO_{X}N_{Y} thin-films, and other non-stoichiometric SiO_{X}N_{Y} thin-films.

Optical filters made with non-stoichiometric SiO_{X1}N_{Y1} thin-films have been presented. Some details of specific materials and film layer patterns have been used to illustrate the invention. However, the invention is not limited to merely these examples. Other variations and embodiments of the invention will occur to those skilled in the art.

We claim:

1. A method for fabricating a non-stoichiometric silicon-oxide-nitride thin-film optical filter, the method comprising:
providing a substrate; and,
using a high-density plasma (HDP) process, depositing a first non-stoichiometric SiO_{X1}N_{Y1} thin-film overlying the substrate, where (X1+Y1<2 and Y1>0), the first non-stoichiometric SiO_{X1}N_{Y1} thin-film having a refractive index (n1) in the range of about 1.46 to 3, and complex refractive index (N1=n1+ik1), where k1 is an extinction coefficient in a range of about 0 to 0.5, at a wavelength between about 350 nanometers (nm) and 550 nm, which is independent of the refractive index.

2. The method of claim 1
wherein the first non-stoichiometric SiO_{X1}N_{Y1} thin-film is a film selected from a group consisting of intrinsic and doped non-stoichiometric SiO_{X1}N_{Y1} thin-films.

3. The method of claim 1 wherein the first non-stoichiometric SiO_{X1}N_{Y1} thin-film includes Si nanoparticles having a size in a range of about 1 to 10 nanometers (nm).

4. The method of claim 1 further comprising:
using the HDP process, depositing a second non-stoichiometric Si_{X2}N_{Y1} thin-film overlying the first non-stoichiometric SiO_{X1}N_{Y1} thin-film, where X2+Y2<2, Y2>0, and Y1≠Y2, selected from a group consisting of intrinsic and doped non-stoichiometric SiO_{X1}N_{Y1} thin-films.

5. The method of claim 1 further comprising:
using the HDP process, depositing a stoichiometric SiO_{X2}N_{Y2} thin-film overlying the first non-stoichiometric SiO_{X1}N_{Y1} thin-film, selected from a group consisting of intrinsic and doped stoichiometric SiO_{X2}N_{Y2} thin-films.

6. The method of claim 1 wherein the first non-stoichiometric SiO_{X1}N_{Y1} thin-film has a graded first refractive index (n1).

7. The method of claim 6 wherein the first non-stoichiometric SiO_{X1}N_{Y1} thin-film has a graded refractive index with a function selected from a group consisting of continuous, stepped, and cyclic.

8. The method of claim 6 wherein the first non-stoichiometric SiO_{X1}N_{Y1} thin-film with the graded refractive index has a Y1 value that varies with the distance of the film from the substrate.

9. The method of claim 1 further comprising:
forming a second film layer overlying the first non-stoichiometric SiO_{X1}N_{Y1} thin-film with a second refractive index (n2).

10. The method of claim 9 wherein the combination of the first non-stoichiometric SiO_{X1}N_{Y1} thin-film and the second film has an overall third refractive index (n3).

11. The method of claim 10 further comprising:
forming a plurality of films overlying the first non-stoichiometric SiO_{X1}N_{Y1} thin-film; and,
wherein the combination of the first non-stoichiometric SiO_{X1}N_{Y1} thin-film and the plurality of overlying film layers has an overall fourth refractive index (n4).

12. The method of claim 11 wherein forming the plurality of films overlying the first non-stoichiometric SiO_{X1}N_{Y1} thin-film includes:
forming the second film covering a first area of the first non-stoichiometric SiO_{X1}N_{Y1} thin-film and exposing a second area of the first non-stoichiometric SiO_{X1}N_{Y1} thin-film;
forming a third film covering a first area of the second film and exposing a second area of the second film;
wherein the refractive index through the first area of the non-stoichiometric SiO_{X1}N_{Y1} thin-film, the first area of the second film, and the third film layer is the fourth refractive index;
wherein the refractive index through the first area of the non-stoichiometric SiO_{X1}N_{Y1} thin-film and the second area of the second film layer is the third refractive index; and,
wherein the refractive index through the second area of the non-stoichiometric SiO_{X1}N_{Y1} thin-film is the first refractive index.

13. The method of claim 10 wherein the second film covers a first area of the first non-stoichiometric SiO_{X1}N_{Y1} thin-film and exposes a second area of the first non-stoichiometric SiO_{X1}N_{Y1} thin-film;
wherein the refractive index through the first area of the non-stoichiometric SiO_{X1}N_{Y1} thin-film and the overlying second film layer is the third refractive index; and,
wherein the refractive index through the second area of the non-stoichiometric SiO_{X1}N_{Y1} thin-film is the first refractive index.

14. The method of claim 1 further comprising:
forming a grating overlying the first non-stoichiometric SiO_{X1}N_{Y1} thin-film, having diffraction and reflection characteristics, to control incident light introduced to the first non-stoichiometric SiO_{X1}N_{Y1} thin-film.

15. The method of claim 14 wherein the grating includes a phosphor material.

16. The method of claim 1 wherein the substrate is a material selected from a group consisting of plastic, glass, quartz, ceramic, metal, polymer, undoped Si, doped Si, SiC, Ge, Si₁₋ₓGeₓ, InGaAs, GaN, GaP, Si-on-insulator (SOI), Ge-on-insulator (GOI), silicon-containing materials, and semiconductor materials.

17. The method of claim 1 further comprising:
forming a film overlying the first non-stoichiometric SiO_{X1}N_{Y1} thin-film, made from a material selected from a group consisting of dielectrics, semiconductors, organic thin-films, polymer, undoped Si, doped Si, amorphous Si, polycrystalline Si, single-crystal Si, SiC, Ge, amorphous Si₁₋ₓGeₓ, polycrystalline Si₁₋ₓGeₓ, and single-crystal Si₁₋ₓGeₓ.

18. The method of claim 1 wherein forming the first non-stoichiometric SiO_{X1}N_{Y1} thin-film includes forming a non-stoichiometric SiO_{X1}N_{Y1} thin-film with a dopant selected from a group consisting of Periodic Table Group 3, Group 4, Group 5, and rare earth elements.

19. The method of claim 1 wherein the first non-stoichiometric SiO_{X1}N_{Y1} thin-film has a tunable refractive index.

20. The method of claim 19 wherein the first non-stoichiometric SiO_{X1}N_{Y1} thin-film has a refractive index tunable to an extrinsic environmental condition selected from a group consisting of temperature, electric field, light, and pressure.

21. A method for fabricating a non-stoichiometric silicon-oxide-nitride thin-film optical filter, the filter comprising:
providing a substrate;
forming a multilayered film structure overlying the substrate as follows:
using a high-density plasma (HDP) process, depositing a non-stoichiometric SiO_{X1}N_{Y1} thin-film, where (X1+Y1<2 and Y1>0), the non-stoichiometric SiO_{X1}N_{Y1} thin-film having a refractive index (n1) in the range of about 1.46 to 3, and complex refractive index (N1=n1+ik1), where k1 is an extinction coefficient in a range of about 0 to 0.5, at a wavelength between about 350 nanometers (nm) and 550 nm, which is independent of the refractive index; and,
forming a film overlying the non-stoichiometric SiO_{X1}N_{Y1} thin-film, having diffraction and reflection characteristics, to control incident light, selected from a group consisting of a diffraction grating and a phosphor material film.
